(19) United States
(12) Patent Application Publication
(10) Pub. No.: US 2011/0279950 A1
(43) Pub. Date: Nov. 17, 2011

(54) Elastic device, slide module and portable electronic equipment utilizing the device

(76) Inventor: Han Sang LEE, Seoul (KR)

(21) Appl. No.: 13/106,370

(22) Filed: May 12, 2011

(30) Foreign Application Priority Data
May 14, 2010 (KR) 10-2010-0045493

(51) Int. Cl. H05K 5/02; F16C 29/00; F16C 29/02; F16F 1/10

(52) U.S. Cl. 361/679.01; 267/155; 384/10

(57) ABSTRACT

An elastic device which can be used where there is an interval smaller than the thickness of the spring in a moving range of an arm member. The elastic device includes a spring, a first arm member for receiving at least a part of the spring inside, supporting or fixing an end of the spring, and including a housing portion having an opening along one side and an extension extending outside of the housing portion, and a second arm member for supporting or fixing the other end of the spring in at least one end, including a rotation-supporting portion installed rotationally to the first arm member while overlapping with the spring in the housing portion and an exposing-extension portion connected to the rotation-supporting portion and exposed to outside of the housing portion through the opening.

### FIELD OF TECHNOLOGY

The present invention relates to an elastic device, a slide module, and a portable electronic equipment utilizing the device, and more particularly to an elastic device suitable to be used in a slide module of a slide-type portable terminal such as wireless phone, PDA, PMP, portable game machine, etc., a slide module utilizing the elastic device, and portable electronic equipment.

### BACKGROUND OF TECHNOLOGY

The background of the technology is disclosed in FIGS. 34-36 of the Korean Patent Application Publication 10-2008-0005087 (referred as ‘previous application’ below) by the inventor of the present invention, in which an elastic device is formed by engaging arm members connected to springs, etc. with two plates facing each other and the winding member of the spring is received between the two plates.

### DESCRIPTION OF INVENTION

### Problems to Solve

The present invention is for improving or utilizing the invention of the previous application by the inventor. Among the disclosures in the Drawings of the previous application, the arm member having two plate portions facing and engaging each other cannot be used in cases where there exists a gap having a small interval of the thickness of the plate portion within the rotational range of the arm members because two plate portions of the same length facing and engaging each other have the same thickness all along the entire length. Also, the elastic device disclosed in the Drawings of the previous application cannot be used in a case in which there is an interval smaller than the thickness of the spring wire in the rotational portion of the arm member. What was disclosed in the Drawings of the previous application cannot be used in a case in which there is an obstacle protruding in side direction or upward or downward in the rotational range of the arm member. Also, what was disclosed in the Drawings of the previous application is hard to assemble and its component for assembling gets bigger because the two plate portions should be assembled along the entire edges.

The objective of the present invention is to provide an elastic device, which has receiving portion for receive a part of spring inside, can be installed where there is an interval smaller than the prior art in the rotational range of the arm member, and saves materials.

Another objective of the invention is to provide an elastic device, which has a housing portion for receiving a part of spring inside and can be installed where there is an interval smaller than the thickness of a spring wire in the rotational range of the arm member.

Still another objective of the invention is to provide an elastic device, which can be used where there is an obstacle sideways or upward or downward in the rotational range of the arm member.

Still another objective of the invention is to provide an elastic device, which reduces the length of engaging compared to the prior art.

Still another objective of the invention is to provide a slide module, which uses an elastic device according to the present invention.

Still another objective of the invention is to provide a portable electronic device, which uses an elastic device according to the invention.

### Solutions to Problems

An elastic device according to the present invention comprises: a spring; a first arm member for receiving at least a part of the spring inside, supporting or fixing an end of the spring, and including a housing portion having an opening along one side and an extension extending outside of the housing portion; and a second arm member for supporting or fixing the other end of the spring in at least one end, including a rotation-supporting portion installed rotationally to the first arm member while overlapping with the spring in the housing portion and an exposing-extension portion connected to the rotation-supporting portion and exposed to outside of the housing portion through the opening.

The spring is a torsion spring having a winding portion in a shape of whirl, and the housing portion preferably contains the winding portion within.

The extension of the first arm member is preferably a thin-plate extension.

In the housing portion is formed a circular hinge portion which is formed by pressing-in, and in the second arm member inside the housing portion may be preferably formed a through-hole or arc-shaped protrusion for engaging rotatably to the hinge portion.

The second arm member is made of a thin plate, and in the second arm member may be formed a latching portion which latches to an end portion of the opening and a second spring-supporting portion which extends toward where the spring is installed and support-or-fixes the other end of the spring.

In cases, in the thin-plate extension or the exposing-extension portion may be formed a bent portion which is bent in a direction of thickness.

In the housing portion is installed the hinge portion of a ring shape, and in the second arm member in the housing portion may be formed a through-hole for engaging rotatably to the hinge portion.

The slide module according to the invention comprises: a guide member having a guiding portion; a slide member having a guided portion guided by the guide portion and engaging slidably along the guiding portion while overlapped with the guide member; and an elastic device according to the invention disposed between the guide member and the slide member and having one end connected rotatably to the guide member and the other end connected rotatably to the slide member.

A portable electronic device according to the invention includes a device body having a guiding portion and a cover engaging slidably to the device body through the guiding portion, and one end thereof is connected rotatably to the device body and the other end thereof is connected rotatably to the cover.

### Effects of Invention

Since a spring is received inside a housing portion, an elastic device according to the invention is stable, has a shorter length of engaged portion, can be used where there is a relatively small interval compared to the prior arts in a rotational range of arm member, and can be used where there is an interval smaller than the thickness of a spring wire in a rotational range of arm member.

Also, an elastic device according to the invention can be used where there is a protrusion sideways, upward or downward in a rotational range of arm member, have a thin-plate extension of the arm member formed variously according to usage, and can have the arm member formed in various thickness and shapes.

### BRIEF DESCRIPTION OF DRAWINGS

FIG. 1 is a perspective view showing an elastic device according to the present invention;

FIG. 2 is an exploded partial perspective view showing the elastic device of FIG. 1;

FIG. 3 is a plan view showing relationship among elements of the elastic device of FIG. 1;

FIG. 4 is an exploded perspective view showing the elastic device of FIG. 1;

FIG. 5 is an exploded bottom plan view showing the elastic device of FIG. 1;

FIG. 6 is a perspective view showing a variant of the elastic device of FIG. 1;

FIG. 7 is an exploded perspective view showing the elastic device of FIG. 6;

FIG. 8 is an exploded partial perspective view showing an elastic device according to another embodiment of the invention;

FIG. 9 is an exploded perspective view showing the elastic device of FIG. 8;

FIG. 10 is an exploded perspective view showing a variant of FIG. 9;

FIG. 11 is an exploded perspective view showing an elastic device according to still another embodiment of the invention;

FIG. 12 is an exploded perspective view showing an elastic device according to still another embodiment of the invention;

FIG. 13 is a perspective view showing an elastic device according to still another embodiment of the invention;

FIG. 14 is a perspective view showing an elastic device according to still another embodiment of the invention;

FIG. 15 is an exploded perspective view showing an elastic device according to another embodiment of the invention;

FIG. 16 is a plan view showing an elastic device according still another embodiment of the invention;

FIG. 17 is an exploded perspective view showing a portable electronic device applied with an elastic device according to the invention;

FIG. 18 is a perspective view showing a variant of FIG. 6;

FIG. 19 is an exploded perspective view showing the elastic device of FIG. 18;

FIG. 20 is a figure viewed from a bottom of FIG. 19;

FIG. 21 is a perspective view showing a variant of FIG. 6;

FIG. 22 is an exploded perspective view showing the elastic device of FIG. 21;

FIG. 23 is an exploded perspective view showing an elastic device according to still another embodiment of the invention; and

FIG. 24 is an exploded perspective view viewed from a bottom of FIG. 23.

### DETAINED DESCRIPTION OF EMBODIMENTS OF INVENTION

Below, desirable embodiments of the present invention are described in detail referring to the drawings.

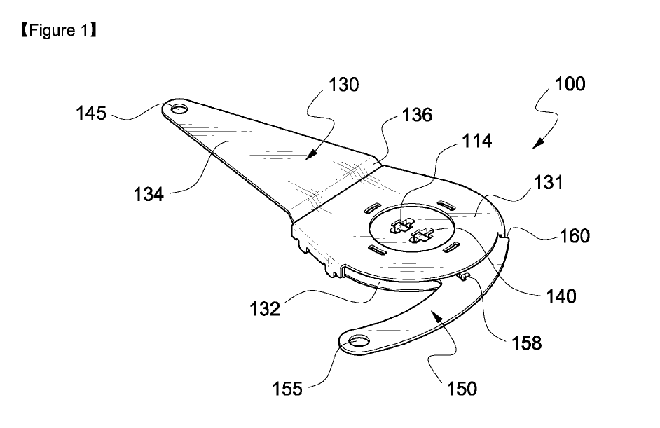

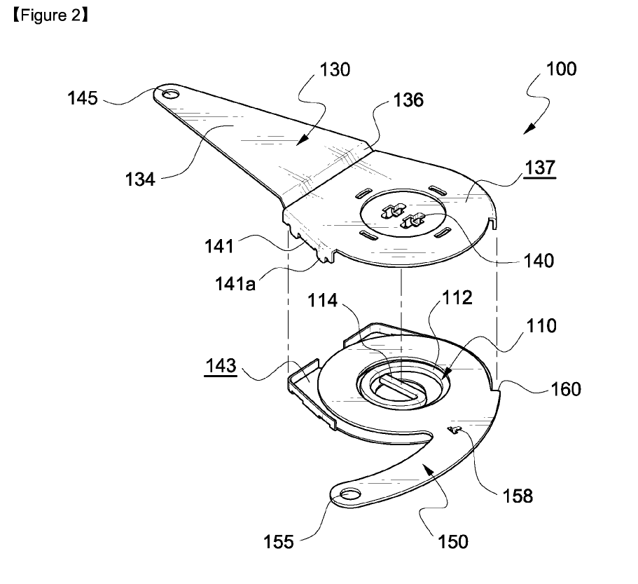

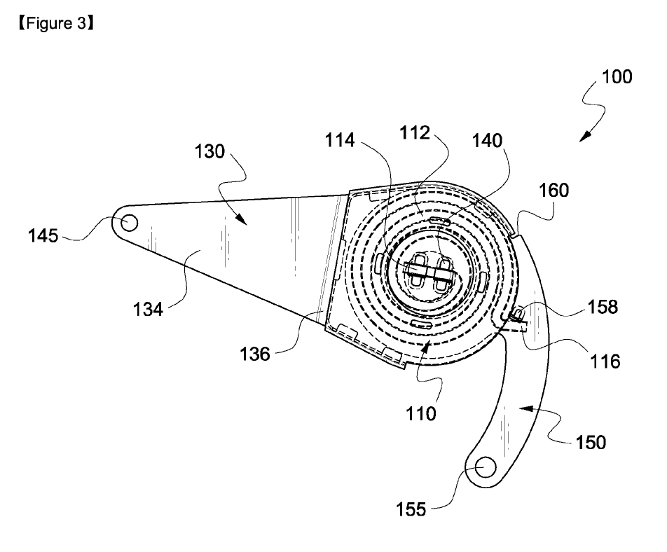

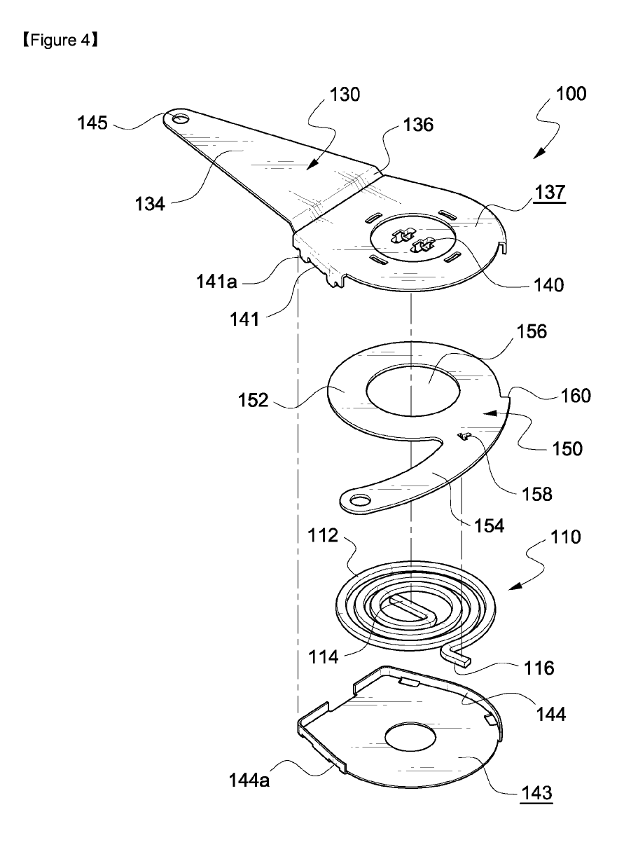

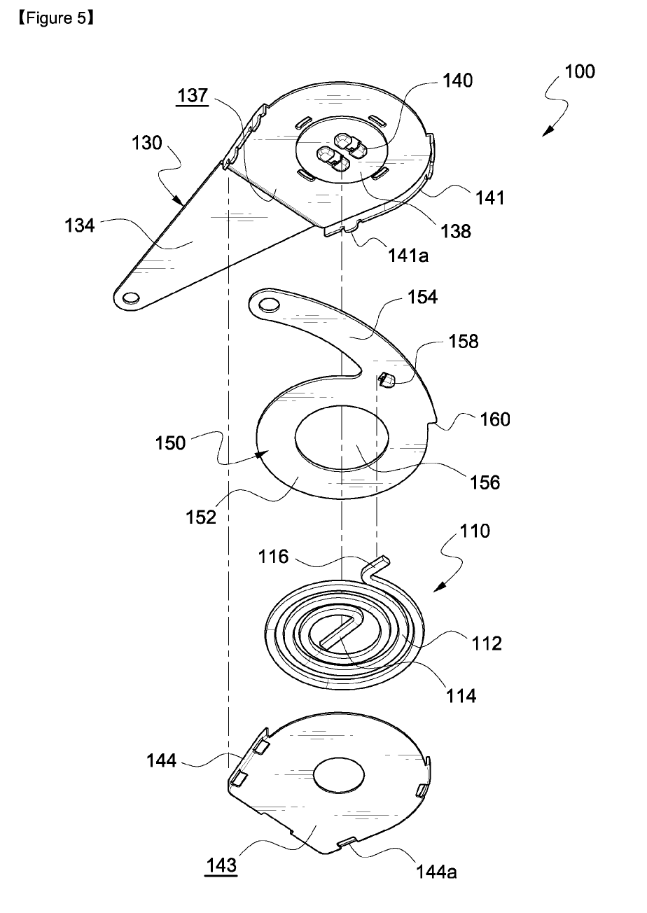

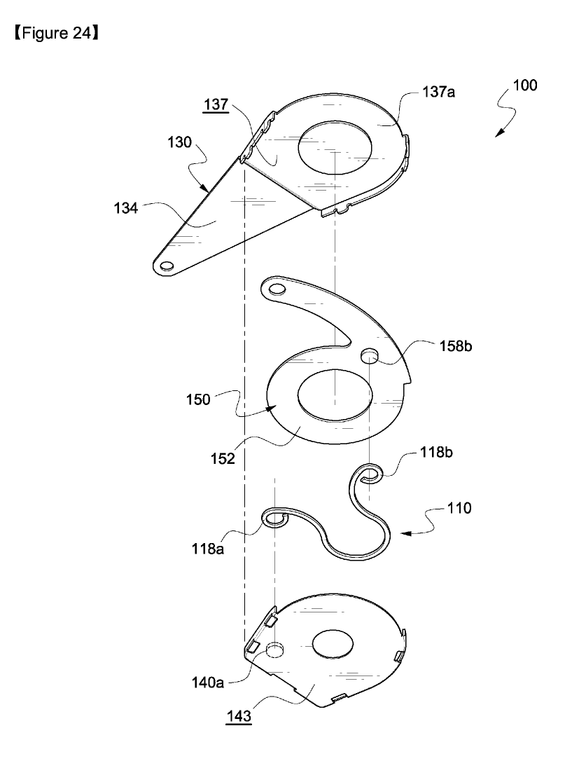

FIG. 1 is a perspective view showing an elastic device according to the present invention, FIG. 2 is an exploded partial perspective view showing the elastic device of FIG. 1, FIG. 3 is a plan view showing relationship among elements of the elastic device of FIG. 1, FIG. 4 is an exploded perspective view showing the elastic device of FIG. 1, and FIG. 5 is an exploded bottom plan view showing the elastic device of FIG. 1. As shown in FIGS. 1-5, the elastic device 100 according to the invention comprises a spring 110 having a winding portion 112 that is wound in a shape of whirl. In the an inner end portion and an outer end portion of the winding portion 112 of the spring 110 are formed end portions 114, 116 that are supported or fixed at a first arm member 130 and a second arm member 150 respectively. In this embodiment, the end portions 114, 116 have a shape bent horizontally, but in cases they can be bent upward or downward, inserted through holes formed at corresponding locations on a thin-plate, and supported or fixed. In this embodiment, using an elastic device 100 without overlapped portion is described, but in cases where the thickness of a housing portion 131 can be large a spring with overlapping can be used. Furthermore, other types of springs can be used instead of a torsion spring having the winding portion in a shape of whirl. The reason is that they can be used as long as they can support elastically in a rotational direction between the first arm member 130 and the second arm member 150 rotatably connected with each other. This can be seen referring to FIGS. 23 and 24.

The elastic device 100 according to the invention includes the first arm member 130. The first arm member 130 includes the housing portion 131 that receives the winding portion 112 inside, supports or fixes the inner end portion 114 of the spring 110, and has an opening portion 132 formed along one side. One side of the housing portion 131 is formed a thin-plate extending portion 134 extending in a direction opposite to the opening portion 132. Since the thin-plate extending portion 134 can be made thinner than the thickness of spring wire forming the spring 110, it can be used where there is an interval between the two members, which is smaller than the thickness of spring wire forming the spring 110. When the location where the thin-plate extending portion 134 is installed is higher than a top surface of the housing portion 131, a bent portion 136 bending upward may be formed. The direction of bending of the bent portion 136 may change in cases, and in some cases the bent portion 136 may be omitted.

As can be seen in FIGS. 4 and 5, in the thin-plate portion 137 out of two thin-plate portions 137, 143 forming the housing portion 131 is formed a circular hinge portion 138, which is pressed in and protrudes inward. The hinge portion 138 is for supporting the second arm member 150 in place rotatably, which is going to be described later. In such a hinge portion 138 is formed a first spring-supporting portion 140, to which the inner end portion 114 of the spring 110 is supported or fixed. The first spring-supporting portion 140 may be preferably formed by pressing in inward. Fixing or supporting of the end portion of spring may be performed in other various types. When the kind of spring changes in some cases, both end portions of the spring may have to be connected to the first and second arm members 140 and 150 rotatably.

The housing portion 131 may be formed by facing and engaging the two thin-plate portions 137, 143 having edges 141, 144. Engaging of the two edges 141, 144 may be preferably formed after forming a plurality of protrusions 141a and protrusion-engaging grooves 144a formed on or around the edges 141, 144 with an interval. The two thin-plate portions 137, 143 may be engaged with each other by welding, etc. in cases.

The elastic device 100 according to the invention includes a second arm member 150. The second arm member 150 includes a rotation-supporting portion 152 that is installed rotatably to the hinge portion 138 while overlapped with the winding portion 112 inside the housing portion 131 and an exposure-extending portion 154 that is exposed outside the housing portion 131 through the opening portion 132, and at least one portion supports or fixes the outer end portion 116 of the spring 110. Also, in the rotation-supporting portion 152 is formed a circular through-hole 156 that engages to the hinge portion 138. In one side of the exposure-extending portion 154 of the second arm member 150 is formed protruding downward a second spring-supporting portion 158 to which the outer end portion 116 of the spring 110 can be latched. Also, in the outer edge of the second arm member 150 is formed a latching portion 160 that extrudes sideways and is latched to an end portion of the housing portion 131 so as to prevent the second arm member 150 from rotating further against the first arm member 130. Of course, the outer end portion 116 of the spring 110 may be fixed or supported to the rotation-supporting portion 152. Also, the latching portion 160 may be formed so as to be latched to one side of the rotation-supporting portion 152 and the housing portion 131 in the corresponding location at a predetermined rotational angle. Such a second arm member 150 is preferably made with a thin plate thinner than the thickness of the spring wire. Preferably, the exposure-extending portion 154 has a circular arc shape, but it may have a linear shape.

In the outer end portions of the first arm member 130 and the second arm member 150 are formed holes 145, 155 that can be connected rotatably to members that are installed, respectively. Instead of the holes 145, 155 a hinge axle may be installed.

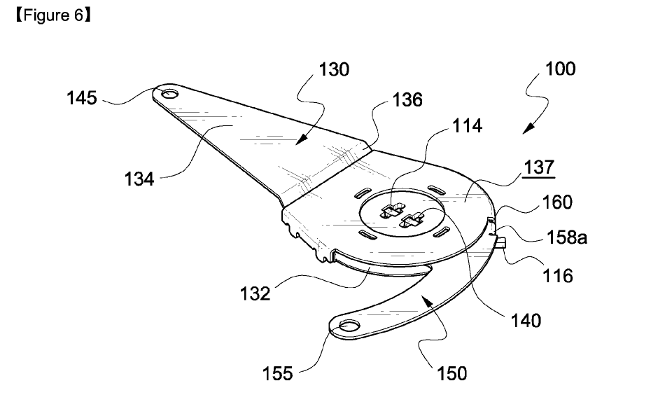

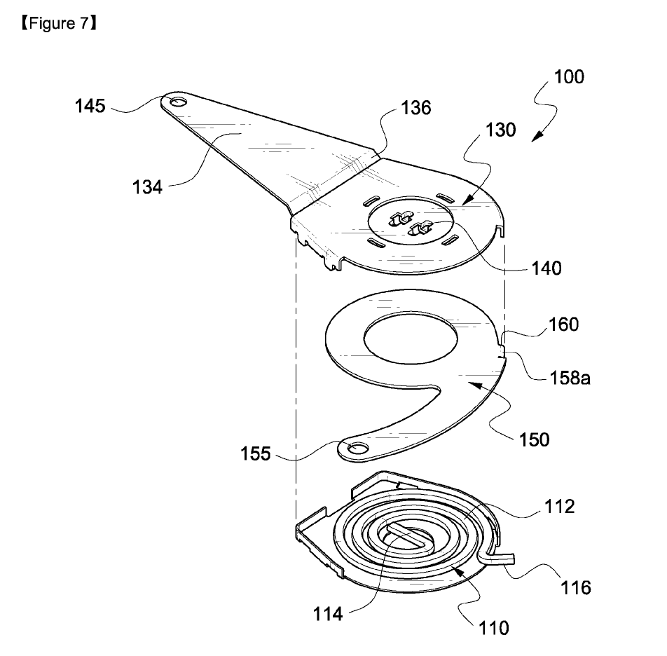

FIG. 6 is a perspective view showing a variant of the elastic device of FIG. 1, and FIG. 7 is an exploded perspective view showing the elastic device of FIG. 6. A second spring-supporting portion 158a that is formed in the second arm member 150 in some cases may be formed by bending a part of the outer edge portion of the second arm member 150 downward. In such a case the second spring-supporting portion 158a performs a function of a latching portion 160 that is latched at an end portion of the opening portion 132 and limits the rotational angle of the second arm member 150. Here, the latching portion 160 and the second spring-supporting portion 158a are preferably formed at a location of a same radius as the edges 141 or 144. The rest is same as explained referring to FIGS. 1-5.

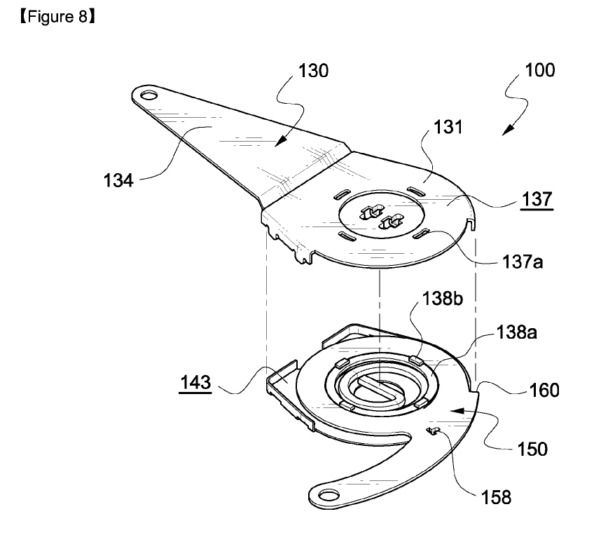

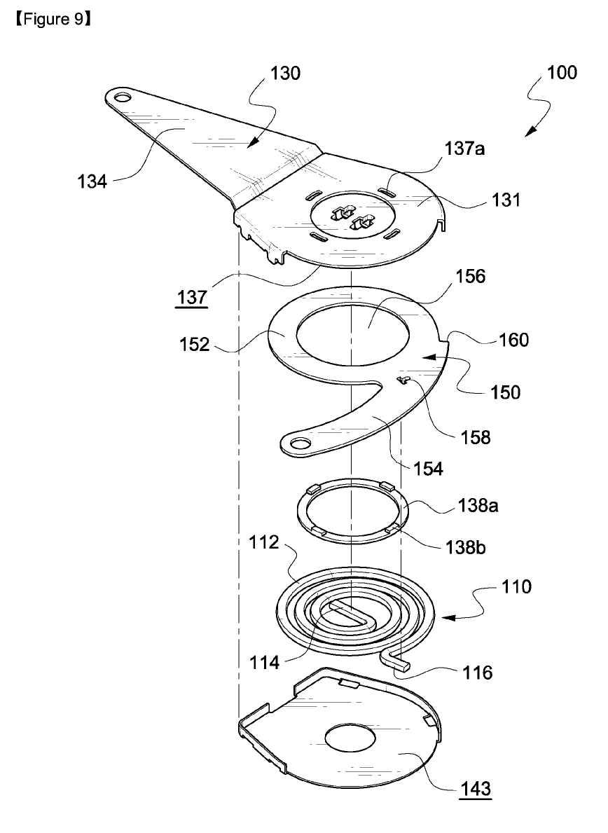

FIG. 8 is an exploded partial perspective view showing an elastic device according to another embodiment of the invention, and FIG. 9 is an exploded perspective view showing the elastic device of FIG. 8. In cases, the elastic device according to the invention may be formed by forming holes 137a for fixing the hinge portion 138a of ring shape to the thin-plate portion 137, forming protrusions 138b at corresponding sides of the hinge portion 138a of ring shape, installing the ring-shaped hinge portion 138a fixedly inside the housing portion 131, and engaging the second arm member 150 rotatably in place. In such a case, in the second arm member 150 is formed a through-hole 156 of a diameter larger than in the previous embodiments so as to engage to the ring-shaped hinge portion 138a. The rest is same as explained referring to FIGS. 1-5.

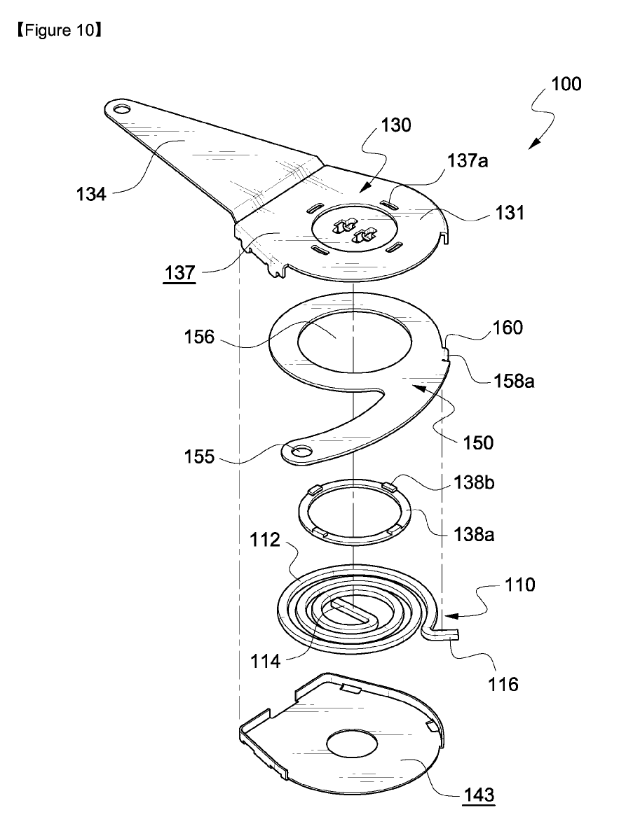

FIG. 10 is an exploded perspective view showing a variant of FIG. 9. In cases, instead of the second arm member 150 of FIG. 8 the one shown in FIGS. 6 and 7 can be used. That is, what is obtained when the second spring-supporting portion 158a bends a part of the outer edge portion of the second arm member 150 downward can be used. The second spring-supporting portion 158a performs a function of a latching portion 160 that is latched to the end portion of the opening portion 132 and limits the rotational angle of the second arm member 150, and is formed at a location of a same radius as the edges 141, 144 of the first arm member 130. The rest is same as explained referring to FIGS. 8 and 9.

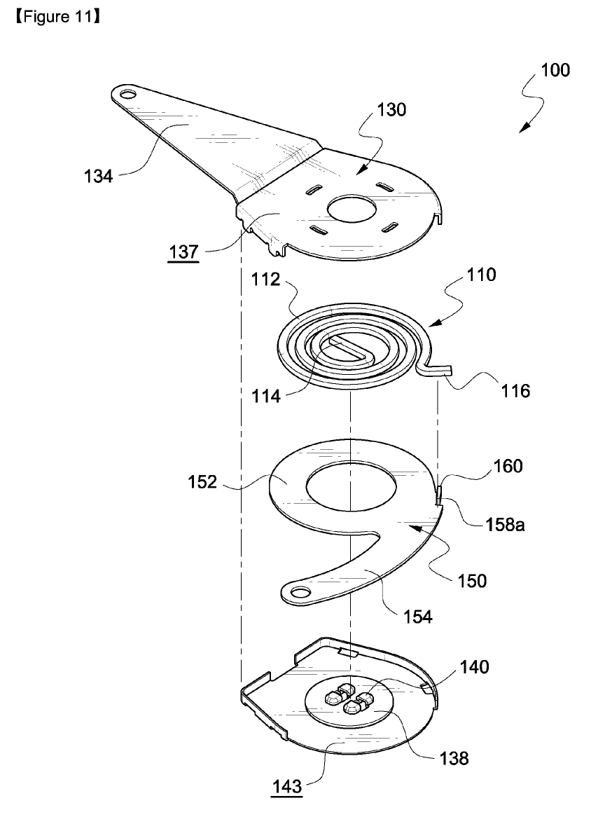

FIG. 11 is an exploded perspective view showing an elastic device according to still another embodiment of the invention. In cases, the second arm member 150 may be disposed below the spring 110. In such a case, the second spring-supporting portion 158a to which the outer end portion 116 of the spring 110 is latched and the latching portion 160 may be formed protruding upward. And, the hinge portion 138 for supporting rotatably the second arm member 150 is formed on the lower thin-plate portion 143 of the housing portion 131 protruding inward, and there is installed the first spring-supporting portion 140. In cases the first spring-supporting portion 140 may be formed in the top thin-plate portion 137. Also, according to necessity in the exposure-extending portion 154 of the second arm member 150 may be formed a bent portion bending upward or downward. The rest is same as explained referring to FIGS. 1-5.

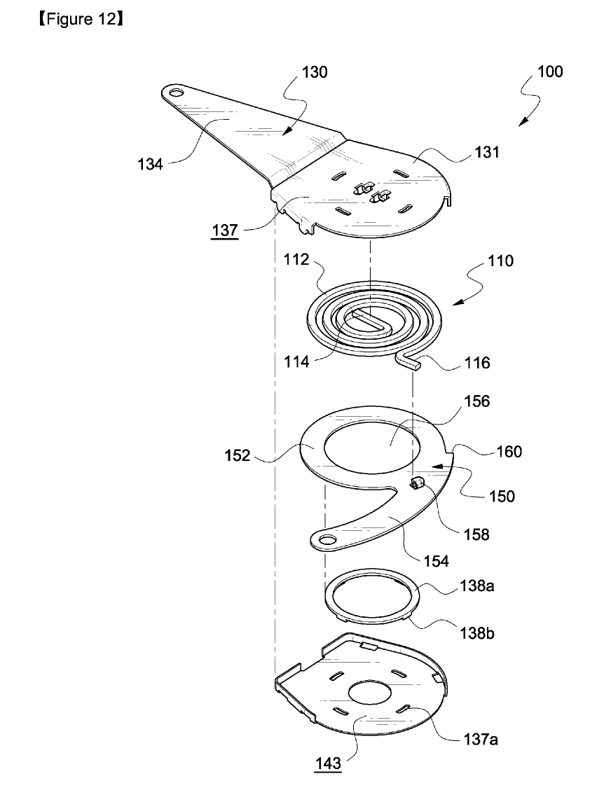

FIG. 12 is an exploded perspective view showing an elastic device according to still another embodiment of the invention. In cases, the second arm member 150 in FIG. 9 may be disposed below the spring 110. In such a case, the ring-shaped hinge portion 138a is fixed to the bottom thin-plate portion 143 of the housing portion 131 through a hole 137a, and for this the protrusion 138b for fixing may be formed with intervals on a bottom portion of the ring-shaped hinge portion 138a. Of course, the second spring-supporting portion 158 is formed protruding upward. The rest is same as in FIG. 9.

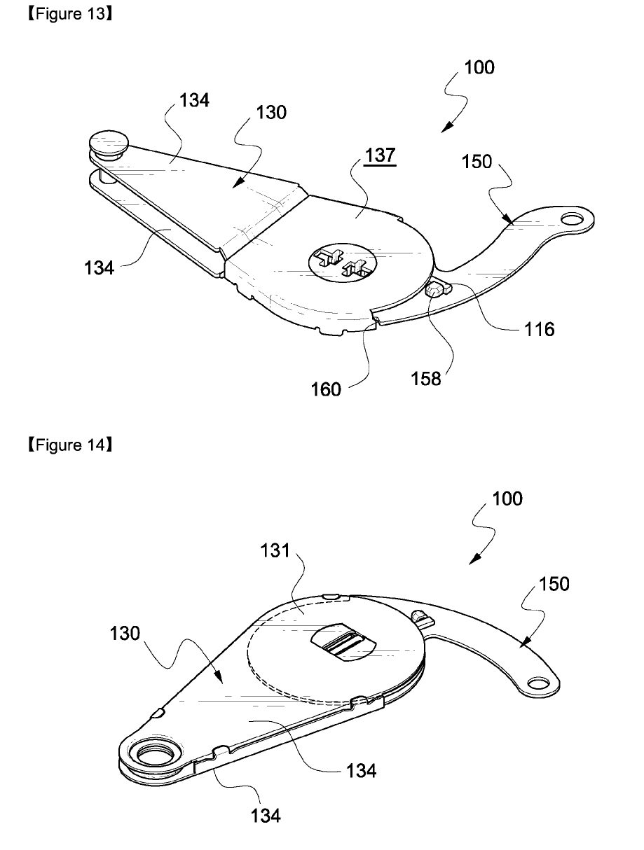

FIG. 13 is a perspective view showing an elastic device according to still another embodiment of the invention. In cases, as for the thin-plate extending portion 134 of the first arm member 130, two of them can be disposed on the top of each other with an interval. In such a case, it can be used even if there is an obstacle inserted between the two thin-plate extending portions 134 when the first arm member 130 rotates. In certain cases, any one of the two thin-plate extending portions 134 is formed with a bent portion in a direction of facing away from each other, in a direction of facing each other, or in a same direction with one bent a little and other bent much more to contact each other. The rest is same as explained referring to FIGS. 1-5.

FIG. 14 is a perspective view showing an elastic device according to still another embodiment of the invention. In cases, the first arm member 130 may be formed so that the perimeters of the two thin-plate extending portions 134 are connected to each other and communicates with the internal space of the housing portion 131 receiving the spring. The rest is same as explained referring to FIGS. 1-5.

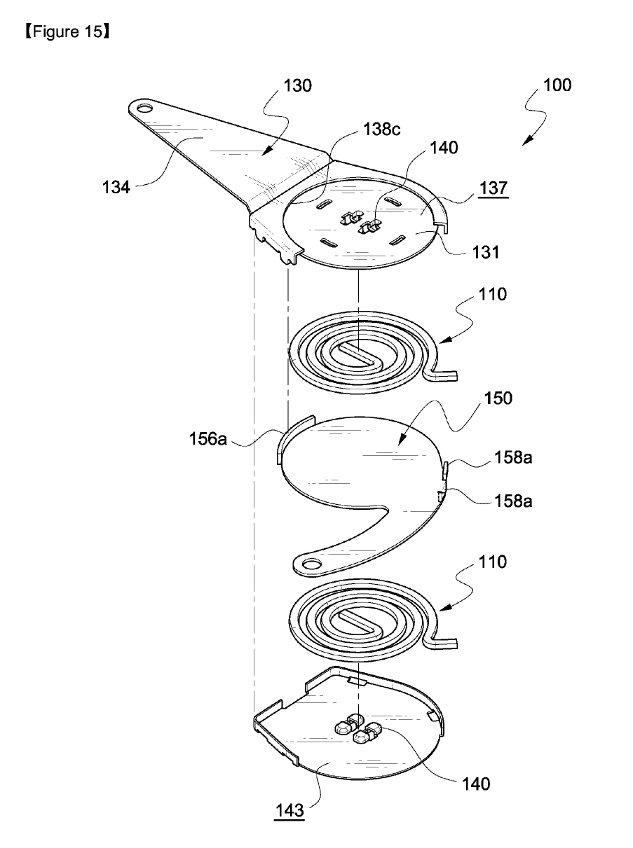

FIG. 15 is an exploded perspective view showing an elastic device according to another embodiment of the invention. In cases, an elastic device 100 according to the invention may be formed by installing springs both above and below the second arm member 150 and forming the first spring-supporting portion 140 on all of the two thin-plate portions 137, 143 respectively. In such a case, the hinge portion 138c formed in the first arm member 130 can be formed large outside the spring 110, and instead of the through-hole in a central portion, in the second arm member 150 at corresponding locations may be formed an arc-shaped protruding portion 156a for receiving guide of the hinge portion 138c at the perimeter. And, the second spring-supporting portions 158a are formed in both directions, upward and downward, respectively. In case of forming the elastic device 100 as in FIG. 15, a large elasticity can be obtained. The rest is same as explained referring to FIGS. 1-5.

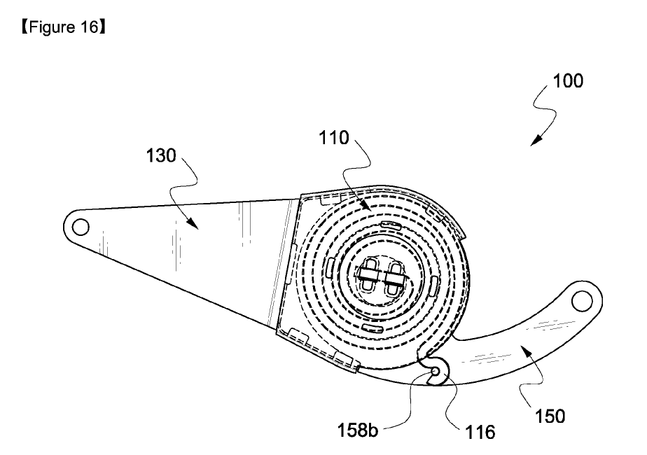

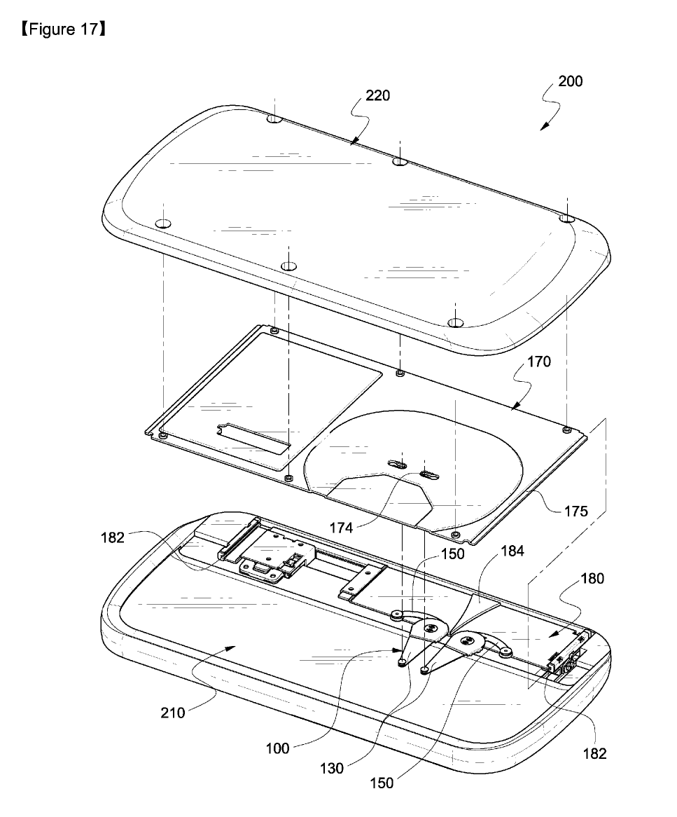

FIG. 16 is a plan view showing an elastic device according still another embodiment of the invention. In cases, the elastic device 100 can be formed such that the elasticity of the spring 110 exerts in a direction opposite to those in the previous embodiments. In such an embodiment, the second arm member 150 receives elasticity for rotating clockwise by the spring 110, and the first arm member 130 receives elasticity counterclockwise. The magnitude of the elasticity exerted to the first arm member 130 and the second arm member 150 by the spring 110 may be adjusted variously.

FIG. 17 is an exploded perspective view showing a portable electronic device applied with an elastic device according to the invention. As shown in FIG. 17, a portable electronic device 200 according to the invention includes a device body 210 having a conventional circuit board, input keys, etc. installed, a cover 220 installed with a display, etc., and a guiding member 180 installed between them. The device body 210 is combined to a bottom side of the guide member 180, and the cover 220 is combined to the top side of the guide member 180. On the bottom surface of the cover 220 is attached the slide member 170, and along the both perimeters of the slide member 170 is formed a guided member 175 that is combined to the guiding portion 182 installed along the both perimeters of the guide member 180 and guided. Between this slide member 170 and the guide member 180 is installed an elastic device 100 described in the above. The first arm member 130 of the elastic device 100 is connected rotatably to the rotation-supporting portion 174 of the slide member 170, and the second arm member 150 is connected to the guide member 180 rotatably. When accordingly the slide member 170 and the cover 220 slide and move along the guiding portion 182, the elastic device 100 exerts an elastic force to and slides the slide member 170 forward or backward according to the moving position of the slide member 170. Here, the slide member 170, the guide member 180, and the elastic device 100 having one end connected to the slide member 170 rotatably and the other end connected to the guide member 180 rotatably form a slide module according to the invention. In case of using an elastic device 100 according to the invention, there exists a protruding portion 184 in a moving range of the first arm member 130 or the second arm member 150, such that even though the interval between the slide member 170 and the protruding portion 184 are very small, it is not a problem.

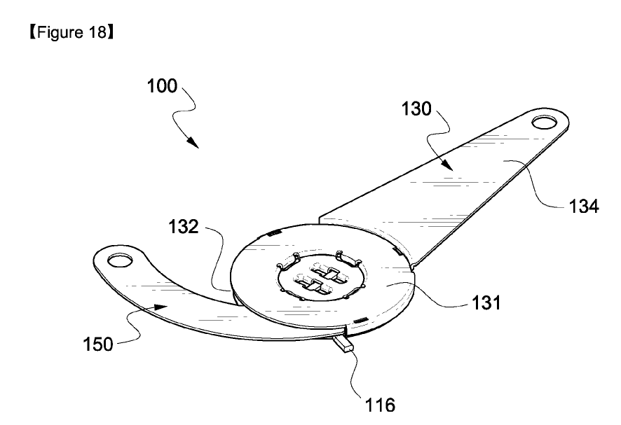

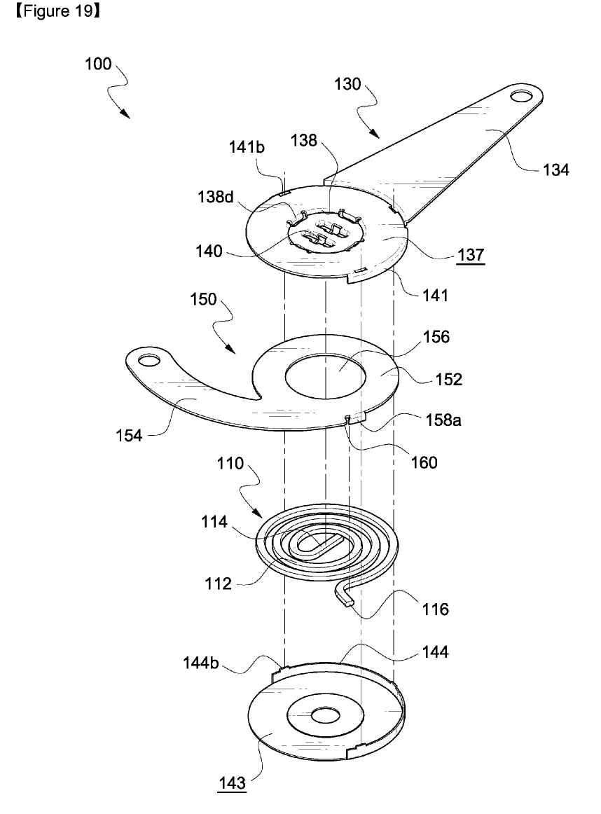

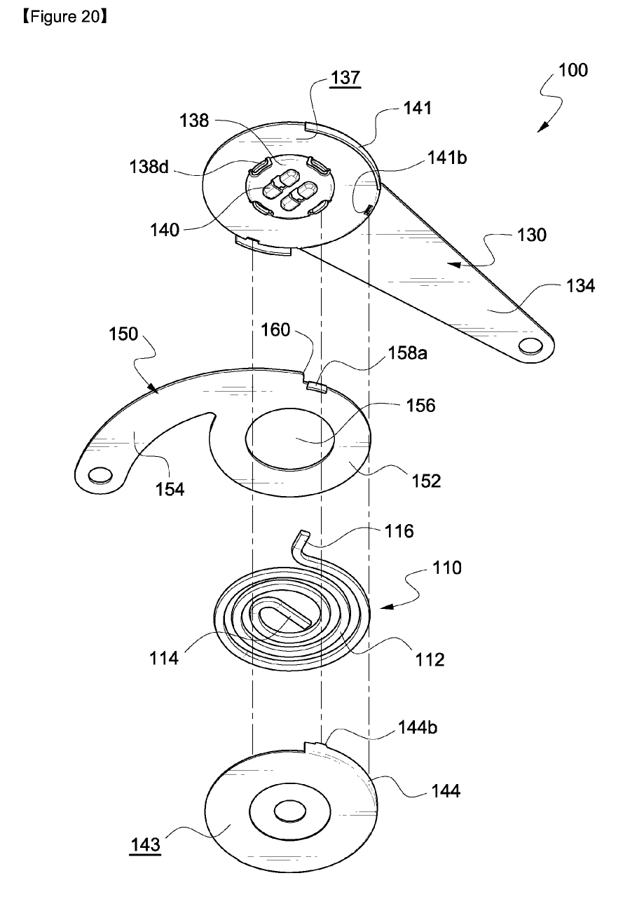

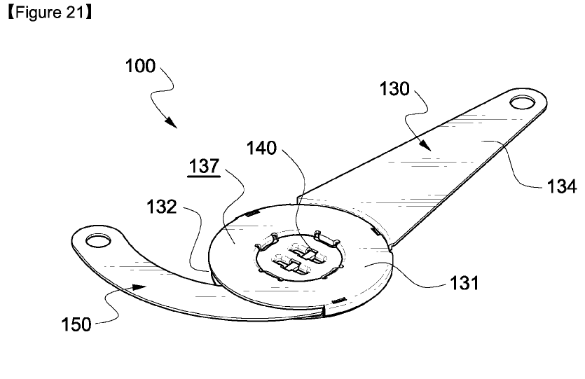

FIG. 18 is a perspective view showing a variant of FIG. 6, FIG. 19 is an exploded perspective view showing the elastic device of FIG. 18, and FIG. 20 is a figure viewed from a bottom of FIG. 19. In cases, a protrusion-engaging groove 141b is formed in the upper thin-plate portion 137, and the protrusion 144b may be formed in the bottom thin-plate portion 143. Also, in the perimeter of the hinge portion 138 is formed a hinge protrusion 138d, such that the second arm member 150 is not disengaged easily when engaged. Besides, the second spring-supporting portion 158a to which the outer end portion 116 of the spring 110 is latched may be moved toward the center of the rotation-supporting portion 152 so as to enter into the housing portion 131 in a state that the second arm member 150 is opened, and then installed. In such a case, the latching portion 160 is latched to the opening portion 132 in a state that the second spring-supporting portion 158a enters the housing portion 131. The rest is same as explained referring to FIGS. 6 and 7.

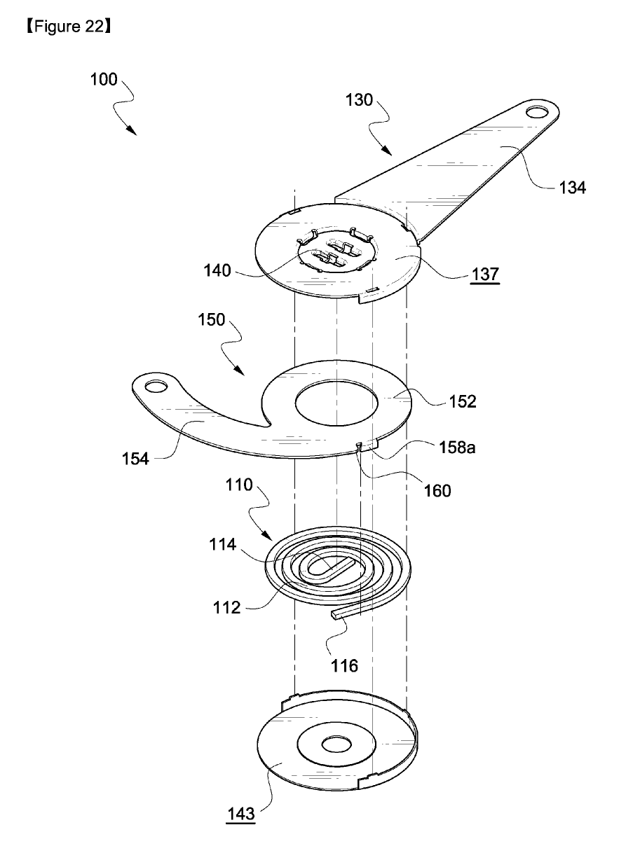

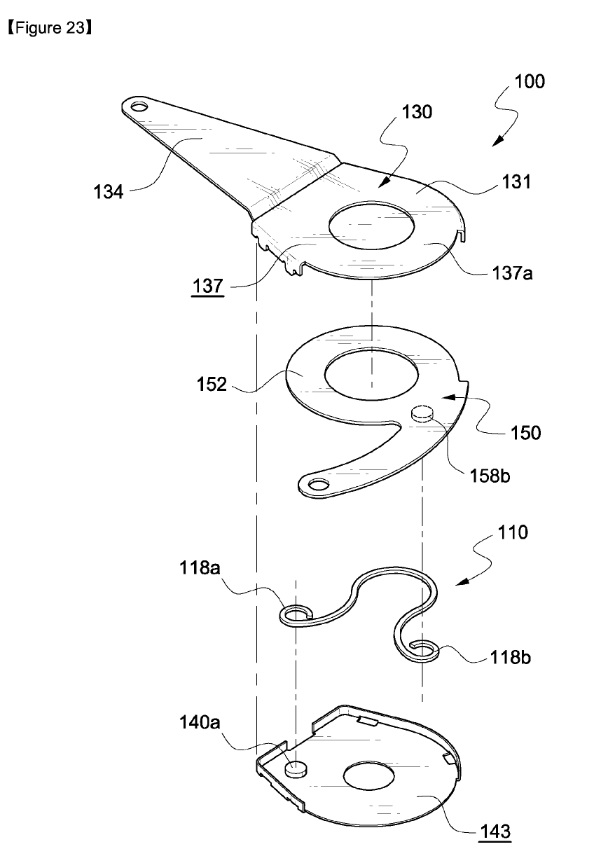

FIG. 21 is a perspective view showing a variant of FIG. 6, and FIG. 22 is an exploded perspective view showing the elastic device of FIG. 21. In cases, the outer end portion 116 of the spring 110 is welded and attached to the second spring-supporting portion 158a. The rest is same as described referring to FIGS. 18-20

FIG. 23 is an exploded perspective view showing an elastic device according to still another embodiment of the invention, and FIG. 24 is an exploded perspective view viewed from a bottom of FIG. 23. In cases, springs other than a torsion spring can be used for the spring 110. As shown in FIGS. 23 and 24, an arc-shaped spring can be used for the spring 110. In such a case, in the bottom thin-plate portion 143 of the first arm member 130 is installed a first hinge protrusion 140a for supporting rotatably one end of the spring 110, and in the second arm member 150 is installed a second hinge protrusion 158b for supporting the other end of the spring 110 rotatably. And, in both ends of the spring 110 are formed rotation-connecting portions 118a, 118b for engaging rotatably to the first hinge protrusion 140a and the second hinge protrusion 158b respectively. In such a case, a spring-supporting portion is not needed for fixing an end of the spring 110 as in the previous embodiments.

Referring to the above embodiments, for the spring 110 of the elastic device 100 according to the invention, various types of springs can be used as long as they can support elastically between the two arm members like bow-shaped spring as well as the torsion spring and the arc-shaped spring. The rest is same as explained in the previous embodiments.

### INDUSTRIAL APPLICABILITY

The elastic device according to the invention may be used for a drawer or door as well as a slide module of a portable electronic device, and can be used for spring devices of various machines.

1. An elastic device comprising:
a spring;
a first arm member for receiving at least a part of the spring inside, supporting or fixing an end of the spring, and including a housing portion having an opening along one side and an extension extending outside of the housing portion; and
a second arm member, at least of end of which supporting or fixing the other end of the spring, including a rotation-supporting portion installed rotationally to the first arm member while overlapping with the spring in the housing portion and an exposing-extension portion connected to the rotation-supporting portion and exposed to outside of the housing portion through the opening.

2. The elastic device of claim 1, wherein the spring is a torsion spring having a winding portion in a shape of whirl or an arc-shaped spring having a shape of arc.

3. The elastic device of claim 1, wherein the extension of the first arm member is a thin-plate extension.

4. The elastic device of claim 1, wherein in the housing portion is formed a circular hinge portion which is formed by pressing-in, and in the second arm member inside the housing portion is formed a through-hole or arc-shaped protrusion for engaging rotatably to the hinge portion.

5. The elastic device of claim 1, wherein the second arm member is made of a thin plate, and in the second arm member is formed a latching portion which latches to a portion protruding from the first arm member or an end portion of the opening formed in the second arm member.

6. The elastic device of claim 1, wherein in the second arm member is formed a spring-supporting portion which extends toward where the spring is installed and supports the other end of the spring or receives and supports the bent portion of the other end of the spring.

7. The elastic device of claim 1, wherein in the second arm member is welded and attached the other end of the spring, such that a spring-supporting portion for supporting the other end of the spring is formed.

8. The elastic device of claim 3, wherein in the thin-plate extension or the exposing-extension portion is formed a bent portion bending in a direction of thickness thereof.

9. The elastic device of claim 1, wherein in the housing portion is installed a ring-shaped hinge portion, and in the second arm member inside the housing portion is formed a through-hole for engaging rotatably to the hinge portion.

10. A slide module comprising:
a guide member having a guiding portion;
a slide member having a guided portion guided by the guide portion and engaging slidably along the guiding portion while overlapped with the guide member; and
an elastic device disposed between the guide member and the slide member and having one end connected rotatably to the guide member and the other end connected rotatably to the slide member,
wherein the elastic device comprising:
a spring;
a first arm member for receiving at least a part of the spring inside, supporting or fixing an end of the spring, and including a housing portion having an opening along one side and an extension extending outside of the housing portion; and
a second arm member, at least of end of which supporting or fixing the other end of the spring, including a rotation-supporting portion installed rotationally to the first arm member while overlapping with the spring in the housing portion and an exposing-extension portion connected to the rotation-supporting portion and exposed to outside of the housing portion through the opening.

11. The slide module of claim 10, wherein the extension of the first arm member is a thin-plate extension.

12. The slide module of claim 10, wherein in the housing portion is formed a circular hinge portion which is formed by pressing-in, and in the second arm member inside the housing portion is formed a through-hole or arc-shaped protrusion for engaging rotatably to the hinge portion.

13. The slide module of claim 10, wherein the second arm member is made of a thin plate, and in the second arm member is formed a latching portion which latches to a portion protruding from the first arm member or an end portion of the opening formed in the second arm member.

14. The slide module of claim 10, wherein in the second arm member is formed a spring-supporting portion which extends toward where the spring is installed and supports the other end of the spring or receives and supports the bent portion of the other end of the spring.

15. The slide module of claim 10, wherein in the housing portion is installed a ring-shaped hinge portion, and in the second arm member inside the housing portion is formed a through-hole for engaging rotatably to the hinge portion.

16. A portable electronic device including a device body having a guiding portion and a cover engaging slidably to the device body through the guiding portion, comprising an elastic device, one end of which is connected rotatably to the device body and the other end of which is connected rotatably to the cover,
wherein the elastic device comprising:
a spring;
a first arm member for receiving at least a part of the spring inside, supporting or fixing an end of the spring, and including a housing portion having an opening along one side and an extension extending outside of the housing portion; and
a second arm member, at least of end of which supporting or fixing the other end of the spring, including a rotation-supporting portion installed rotationally to the first arm member while overlapping with the spring in the housing portion and an exposing-extension portion connected to the rotation-supporting portion and exposed to outside of the housing portion through the opening.

17. The portable electronic device of claim 16, wherein the extension of the first arm member is a thin-plate extension.

18. The portable electronic device of claim 16, wherein in the housing portion is formed a circular hinge portion which is formed by pressing-in, and in the second arm member inside the housing portion is formed a through-hole or arc-shaped protrusion for engaging rotatably to the hinge portion.

19. The portable electronic device of claim 16, wherein the second arm member is made of a thin plate, and in the second arm member is formed a latching portion which latches to a portion protruding from the first arm member or an end portion of the opening formed in the second arm member.

20. The portable electronic device of claim 16, wherein in the housing portion is installed a ring-shaped hinge portion, and in the second arm member inside the housing portion is formed a through-hole for engaging rotatably to the hinge portion.
